(19) United States
(12) Patent Application Publication
(10) Pub. No.: US 2011/0186421 A1
(43) Pub. Date: Aug. 4, 2011

(54) TARGET ASSEMBLY FOR A MAGNETRON SPUTTERING APPARATUS, A MAGNETRON SPUTTERING APPARATUS AND A METHOD OF USING THE MAGNETRON SPUTTERING APPARATUS

(75) Inventors: Hanspeter Friedli, Felsberg (CH); Hartmut Rohrmann, Schriesheim (DE)

(73) Assignee: OC OERLIKON BALZERS AG, Balzers (LI)

(21) Appl. No.: 13/015,892

(22) Filed: Jan. 28, 2011

Related U.S. Application Data
(60) Provisional application No. 61/299,366, filed on Jan. 29, 2010.

(51) Int. Cl. C23C 14/35

(52) U.S. Cl. 204/192.12; 204/298.12

(57) ABSTRACT

To provide, in a magnetron sputtering apparatus for coating a substrate with a material of high magnetic permeability, for a sufficient trapping field of at least 24 kA/m (300 Oe) field strength above a target surface a target assembly consists of target plates (34, 33, 32) separated by through-going slits (35, 36) which the magnetic field must cross and to a support plate (31) consisting of copper to which the backside of the target is fixed. In order to avoid any release of material from the support plate and deposition of the same on the substrate each of the slits (35, 36) is shaped in such a way that there is no line-of-sight connection between the gap at the target surface and the support plate (31) at the backside of the target through the slit, the latter having, e.g., two sections which are perpendicular to the target surface, one ending at the target surface and the other at the support plate, and which are laterally offset and connected by a third section which is parallel to the target surface. Magnetic field strength in the slits (35, 36) is kept below 64 kA/m (800 Oe) to prevent the formation of plasma there.

### FIELD OF THE INVENTION

The present invention concerns a target assembly for a magnetron sputtering apparatus, a magnetron sputtering apparatus comprising such target assembly and a method of using the latter. Magnetron sputtering is used for the deposition of thin films on surfaces. The proposed target assembly, magnetron sputtering apparatus and method for its use are intended for the application of films consisting of high magnetic permeability material, in particular.

### BACKGROUND OF THE INVENTION

Magnetron sputtering is a vacuum deposition method well known in the art. As can be seen in FIG. 1A, an array of magnets 10 and 12 is positioned behind a low permeability target material 14 where the magnetron may produce a discharge of “racetrack” shape. Coupling plate 16 serves to conduct a magnetic field between the lower ends of the two magnets 10, 12. Because of the low permeability of the target material, the magnetic lines of force 18 extend from the magnets and pass through the target material 14 and substantially above the plane of the target surface. An electric field is established perpendicular to at least a portion of the magnetic field. Gas ions accelerated by the electric field strike the target 14, causing it to eject particles.

The looping magnetic field as indicated by the lines of force 18 is necessary to trap the plasma near the surface of the target 14. However, if a high permeability material is used for magnetron sputtering, the magnetic field lines will be concentrated in the target as shown in FIG. 1B. Due to its high permeability the target 15 contains virtually all magnetic lines of force extending from one magnet to the other just like the coupling plate 16. The absence of a looping magnetic field 18 trapping the plasma in the vicinity of the high permeability target material substantially reduces the magnetron sputtering effect.

The materials of interest here exhibit a high saturation magnetization of more than 0.8 Tesla (8000 Gauss).

A number of measures have been proposed for improving magnetron sputtering of such high permeability materials, however, with only limited success.

E.g., a very thin high permeability target is used which by virtue of its small cross section is saturated by a fraction of the magnetic flux produced by the magnets and thus not capable of conducting all of the magnetic field. Unfortunately, if the targets are made thin enough for this effect to appear, the targets are long depleted before a film of sufficient thickness has accumulated on a substrate to be coated.

Of materials with high saturation magnetization only very thin targets can be used, with typical thicknesses of 2.5 mm (NiFe55), 3 mm (NiFe21.5), 6 mm (pure Ni). Materials with higher saturation magnetization like CoFe would require even thinner targets. Target utilization is reduced further due to the target being eroded only on a small part of its surface area (pinching effect). System downtimes are high due to frequent target exchange.

Another possibility of achieving the above-described effect while fairly normal target thicknesses can be employed is the use of high strength magnets. They are, however, difficult to handle, especially during target exchange, and require special safety precautions.

A further known way of sputtering high magnetization material is to use a target assembly 40 with trenches and/or bores, as shown in FIG. 2. A target 46 of high magnetization material is positioned on magnets 42, 43. At the backside a yoke 41 can be arranged. The target 46 will generally contain most, if not all, of the magnetic flux lines but at a trench 44 or a bore 45 the magnetic flux lines are forced out of the target where they must cross the said trench or bore. Plasma can therefore ignite above the latter and enable magnetron sputtering.

Targets with bores have an increased (by a factor of 2-3) lifetime; however, this is still low in comparison with non-magnetic targets. Their usefulness for low-pressure sputtering is limited; the hole-pattern can negatively influence the magnetic alignment of the sputtered layers.

RF sputtering of high magnetization material is in principle possible with most known target designs. However, the maximum possible sputter rate is quite low with this method and there is a large energy flux directed towards the substrate which causes excessive heating of the same and deterioration of the film properties due to the fact that with RF sputtering the sputtering plasma tends to extend to the substrate.

### PRIOR ART

In U.S. Pat. No. 4,391,697 a target assembly conforming to the generic part of claim 1 is proposed with a multiple piece target comprising two or more target plates separated by slits where a plasma source is provided and arranged on a support structure. If the target comprises a high permeability material, the magnetic field permeates the target and the slit where the plasma source is established. As an effect of the slit part of the magnetic field is deviated and forms a weak trapping field above the target which retains the plasma in the vicinity of the target surface.

To allow plasma formation, the through-going slits which are perpendicular to the target surface are more than 1.5 mm, preferably about 3 mm wide and straight. In order to avoid that material from the support structure be released and reach the substrate the bottom of the slit is covered by a ceramic insert. This, however, not only makes the configuration more complicated but the inserts also tend to be coated by target material during the sputtering process, whereby a magnetic shunt is created at the bottom of the slit which captures magnetic lines of force and weakens the trapping field above the target surface.

### SUMMARY OF THE INVENTION

It is the object of the invention to provide a target assembly of the generic type which is of simple configuration and where a trapping field can be established above the target surface which is sufficiently strong for maintaining and confining a plasma there. In addition, there should be virtually no risk of non-target material, in particular material of the support structure holding the target plates, being released during the sputtering process. This object is achieved by the features in the characterising part of claim 1.

In a target assembly according to the invention, in particular, where the dimensions of the slits and the strength of the magnetic field are appropriately chosen, there will be no plasma formation within the slits and the support structure bridging the slits at the backside of the target will be reliably screened from the plasma, such that there is neither a risk of support structure material being released through the slits nor of the support structure at the bottom of the slits being covered by target material.

It is another object of the invention to provide a magnetron sputtering apparatus comprising a target assembly according to the invention and a method of using the said magnetron sputtering apparatus.

The invention provides, in particular, a target assembly for a magnetron sputtering apparatus appropriate for a target material with high permeability and/or saturation magnetization. The target assembly nevertheless has an extended lifetime of more than 100 kWh and is usable in existing production systems like the Oerlikon LLS EVO II where it can be interchanged with other, previously used target assemblies. Further the target assembly provides for the formation of a stable plasma at a pressure of less than 1.5×10⁻³ hPa and at a plasma voltage of less than 650V. Further a good deposition rate on substrates of various sizes can be achieved with, at the same time, good layer deposition homogeneity. Last but not least said rate and distribution are stable over essentially the entire useful lifetime of the target.

The target can have the configuration shown in FIG. 4 with an annular, concentric design (I+III) or an extended design (I+II+III). The target usually consists of a material with high magnetization saturation such as the alloys NiFe, CoFe, NiFeCo.

The magnetron sputtering apparatus can, as shown in FIG. 3, comprise a frame 20, a magnet arrangement 21, and a support plate 22 for a target with, e.g., three target plates 23, 24, 25 separated by slits 26, 27.

### BRIEF DESCRIPTION OF THE DRAWINGS

FIGS. 1A, 1B shows prior art target assemblies for a magnetron sputtering apparatus,

FIG. 2 shows a further prior art target assembly with a bore and trenches,

FIG. 3 schematically shows a longitudinal cross section of an embodiment of the invention with three target plates,

FIG. 4 shows a top view of an embodiment of the invention with an elongated target, and

FIG. 5 shows enlarged a detail from a longitudinal cross section of an embodiment of the invention.

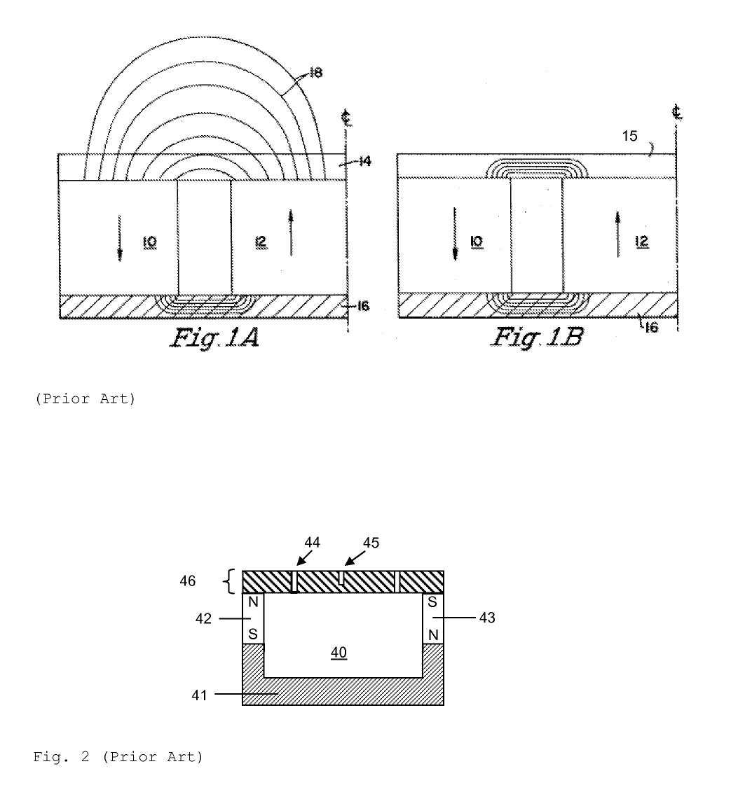

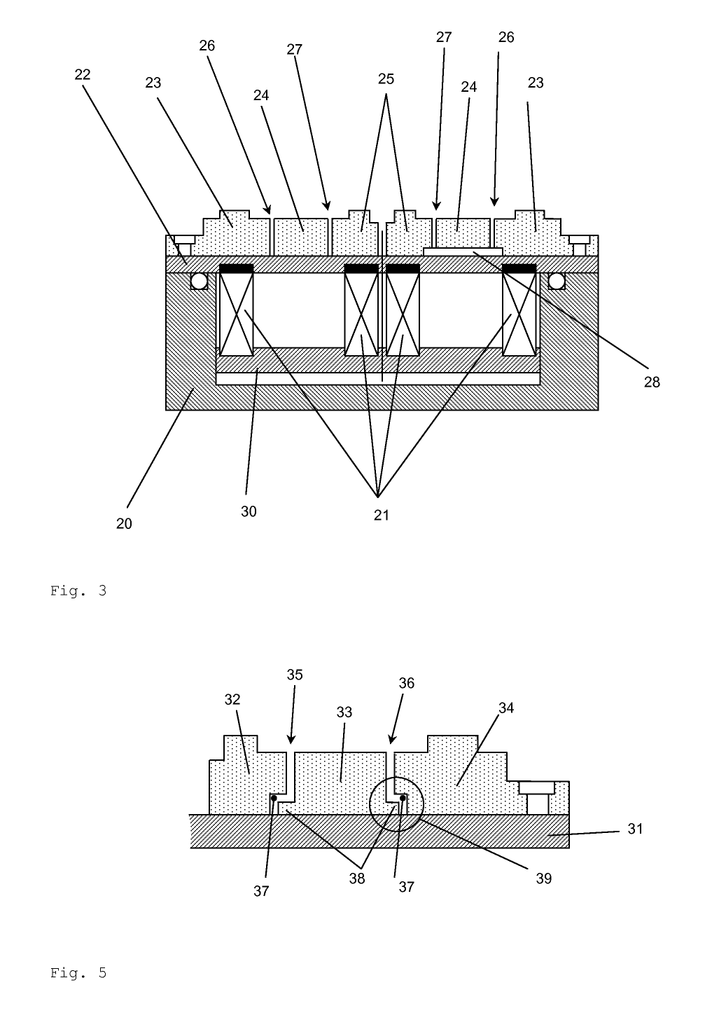

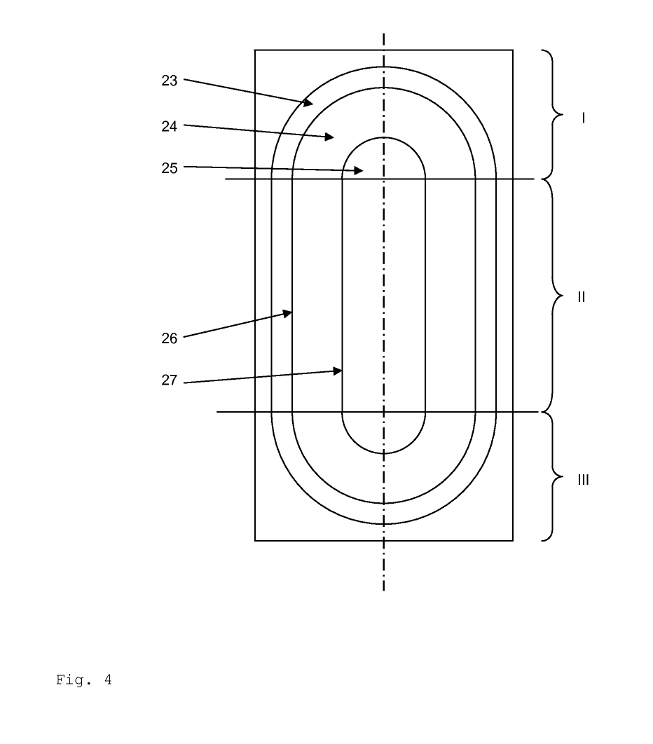

### DESCRIPTION OF THE PREFERRED EMBODIMENTS

The solution will now be described with reference to the figures. Customary accessories like vacuum pumps, electric connectors, cooling systems, gas inlets and the like have been omitted to facilitate understanding. A person skilled in the art will add such equipment without further inventive effort. An inventive target assembly will be arranged in or attached to an opening in a vacuum chamber with means to provide for a sufficient vacuum and supply lines for a working gas for the plasma process such as Argon or Krypton under conditions to be adjusted to the respective pressure regime and flow rate. Commonly used pressure ranges from 6×10⁻⁴ to 6×10⁻² hPa (mbar).

In a first embodiment of the invention the target comprises (FIG. 3) at least three target plates, with an outermost target plate 23, an innermost target plate 25 and at least one intermediate target plate 24. The target plates which each consist of a target material are arranged in an essentially planar configuration on a common support plate 22. Said support plate may consist of copper and have a thickness of, e.g., 3 mm. The target plates 23, 24, 25 are bonded to the support plate by any method known in the art, e.g., by welding, soldering, casting or the like. This has the advantage that the entire target assembly can be mounted or exchanged in one step.

The target surface which faces away from the support plate may be structured or textured as indicated in the Figure.

The following target materials and dimensions have been successfully used:

| Material | Target thickness [mm] |
|---|---|
| NiFe55 | 12 |
| NiFe55 | 9 |
| CoFe60 | 12 |

(NiFe55 = Ni 45at %, Fe 55at %)

Two configurations indicated in FIG. 3 have been compared: One with a magnetic shunt 28 between target plates 23, 24, 25 (consisting, e.g., of target material) or without a shunt (left side of FIG. 3). It has been found that a magnetic shunt 28 should be avoided, since otherwise the magnetic trapping field above the target surface is insufficient.

Slits 26, 27 preferably have a width between 0.5 mm and 1.5 mm, the distance between slits 26, 27 being preferably between 20 mm and 25 mm for a target of the general configuration described above.

To avoid sputtering of support plate material and coating of the support plate 20 by sputtered target material the slits are shaped as shown in FIG. 5. The target assembly comprises a support plate 31 with at least three target plates 32, 33, 34 separated by slits 35, 36. These slits exhibit a labyrinth-like shape 39. From the target surface no material of back plate 31 is visible through the slits 35, 36, i.e., there is no line-of-sight connection between the gap formed by the slit at the target surface and the support plate 31 at the bottom of the slit. The intermediate section 33 of the target assembly has two bulges 38 and each of the adjacent target sections 32, 34 exhibits a clearance 37. Bulge(s) 38 and clearance(s) 37 complement each other in such a way, that the width of the slit(s) 35, 36 is constant.

Of course the arrangement of bulge 38 and clearance 37 may be varied: The bulge may be foreseen at (outer) target plate 32 and/or 34 with the clearance arranged at the intermediate (center) plate 33. In any case the slit 35 or 36 has a first section beginning at the gap formed by the slit at the target surface and extending, virtually perpendicularly to the latter, beyond a middle plane of the target, a second section laterally offset with respect to the first section by somewhat more than the width of the slit, extending from slightly above the level of the end of the first section to the support plate 31 at the backside of the target, and a third section which, being essentially parallel to the target surface, connects the first section with the second section.

The clearances and bulges can be produced by milling the target plates from blanks or by casting target plates in the required shape. The ‘labyrinth’ bends in the cross section of the slit need not be rectangular as shown in FIG. 5, the cross section may be curved or have some other suitable shape. The thickness of bulge 38, as measured perpendicular to the support plate 31 plane, is preferably not smaller than the width of the slit 35, 36.

A target assembly like the one(s) described above is best operated with the magnetic field strength within a certain preferred range. Measurements made 1 mm above the surface of an essentially uneroded target in the region of the slits where the magnetic field has to cross the gap, with slit width of between 0.5 mm and 1.5 mm, have shown that an effective magnetic field strength of at least 24 kA/m (300 Oe) is required for igniting and maintaining a plasma. On the other hand, in the interest of avoiding the formation of plasma within the slits, the magnetic field strength above the target surface should not exceed 64 kA/m (800 Oe), and preferably not be greater than 56 kA/m (700 Oe) for the above range of slit-widths.

Furthermore, magnets 21 should be chosen and arranged at the backside of the target assembly such that the above-mentioned magnetic field strength is essentially equal above both slits 27, 28 or 35, 36, respectively. For achieving a stable plasma the working pressure should preferably not exceed 1.5×10⁻³ hPa.

During operation the target is eroded which also affects the target material bordering on the slits. This effect of the erosion of the target is enhanced by the magnetic flux lines being compressed in the remaining target volume, which results in an increase of magnetic field strength above the target surface and across the slits. The arrangement of bulge 38 and clearance 37 therefore must be such that, when the target has been eroded to a considerable extent and the 56 kA/m (700 Oe) limit is approached, the support plate is still screened from the gap at the target surface, i.e., that there is still no line-of-sight connection between them through the slit.

A magnetron sputtering apparatus with a target assembly according to the invention can be used in methods for coating substrates with films of, in particular, materials having high permeability and/or saturation magnetization with high efficiency and high yield. Target thickness is preferably between 9 mm and 15 mm. Targets with a thickness of 12 mm have been successfully used.

Tests have been performed on a commercially available Oerlikon LLS EVO II coating system, with a rotating tray of 60 cm diameter. 6″ and 8″ Si wafers (thermally oxidized) were clamped to the tray and rotated (2-20 s/turn) about a central axis, thereby passing by the target. The target-substrate distance was, depending on the size of the substrate, 85-100 mm. The DC power applied to the sputter cathodes was varied between 0.5 and 5 kW with a working pressure of Argon between 3.0×10⁻⁴ hPa and 1.7×10⁻³ hPa. Layers between 50 and 300 nm have been deposited.

With prior art target assemblies a life-time of 16 kWh was achieved with a NiFe55 target of 2.5 mm thickness. With a target assembly according to the invention life-time could be extended to 300 kWh using a NiFe55 target of 9 mm thickness. Deposition rate, film uniformity (resistance uniformity) and specific resistance fulfilled the specifications as well.

1. A target assembly for a magnetron sputtering apparatus, with a target exhibiting a target surface and comprising a plurality of target plates each consisting of a target material, and with a contiguous support structure for holding the target plates together to which a backside of the target opposite the target surface is connected, the target plates being separated from each other by through-going slits each extending from a gap in the target surface to the support structure bridging the slit at the backside of the target, each of the slits being shaped in such a way that there is no line-of-sight connection between the gap at the target surface and the support structure bridging the slit at the backside of the target.

2. The target assembly of claim 1, each slit comprising a first section extending from the gap towards the backside of the target in a direction essentially perpendicular to the target surface, a second section extending to the support structure at the backside of the target in a direction essentially perpendicular to the target surface and laterally offset with respect to the first section by a distance which is greater than the width of the first section, and a third section connecting the first section with the second section.

3. The target assembly of claim 2, where the third section extends in a direction essentially parallel to the target surface.

4. The target assembly of claim 1, where each of the slits has a maximum width of at most 1.5 mm.

5. The target assembly of claim 4, where each of the slits has a minimum width of at least 0.5 mm.

6. The target assembly of claim 1, the target comprising a first target plate of oval shape and at least one second target plate of annular shape, the second target plate surrounding the first target plate.

7. The target assembly of claim 1, where each of the target plates has a thickness of between 9 mm and 15 mm.

8. The target assembly of claim 1, where the saturation magnetisation of the target material is at least 0.8 Tesla (8000 Gauss).

9. The target assembly of claim 1, where the target material is a nickel-iron alloy, a cobalt-iron alloy or a nickel-iron-cobalt alloy.

10. The target assembly of claims 1 to 9, the support structure comprising a contiguous support plate covering the backside of the target and to which each target plate is connected, with the support plate consisting of a material of low magnetic permeability.

11. The target assembly of claim 10, the support plate (22; 31) essentially consisting of copper.

12. A magnetron sputtering apparatus for coating a substrate surface with a high magnetic permeability layer, comprising a vacuum chamber and within the vacuum chamber a target assembly with a target exhibiting a target surface and comprising a plurality of target plates, and with a contiguous support structure for holding the target plates together to which a backside of the target opposite the target surface is connected, the target plates being separated from each other by through-going slits each extending from a gap in the target surface to the support structure bridging the slit at the backside of the target, each of the slits being shaped in such a way that there is no line-of-sight connection between the gap at the target surface and the support structure bridging the slit at the backside of the target as well as a plurality of magnets arranged at a backside of the support structure such that the plurality of magnets and the target are comprised in a magnetic loop interrupted by the slits.

13. The magnetron sputtering apparatus of claim 12, where each of the magnets is a permanent magnet and the magnetic field strength immediately above the target surface is at least 24 kA/m (300 Oe).

14. The magnetron sputtering apparatus of claim 13, where each of the magnets is a permanent magnet and the magnetic field strength in the slits is not greater than 64 kA/m (800 Oe).

15. A method of using the magnetron sputtering apparatus of claim 12, the vacuum chamber being filled with Argon or Krypton at a pressure of between 3×10⁻² Pa (3×10⁻⁴ hPa) and 1.7×10⁻¹ Pa (1.7×10⁻³ hPa).
